(19) United States
(12) Patent Application Publication
(10) Pub. No.: US 2026/0123363 A1
(43) Pub. Date: Apr. 30, 2026

(54) SEMICONDUCTOR PACKAGE

(71) Applicant: SAMSUNG ELECTRONICS CO., LTD., Suwon-si (KR)

(72) Inventors: Keunyoung LEE, Suwon-si (KR); Eunhye LEE, Suwon-si (KR)

(73) Assignee: SAMSUNG ELECTRONICS CO., LTD., Suwon-si (KR)

(21) Appl. No.: 19/221,180

(22) Filed: May 28, 2025

(30) Foreign Application Priority Data
Oct. 24, 2024 (KR) 10-2024-0147014

(51) Int. Cl. H01L 21/66; H01L 23/00; H01L 23/538; H01L 25/18; H10B 80/00; H10D 80/30

(52) U.S. Cl. CPC H10P 74/273; H10W 70/611; H10W 70/635; H10W 70/65; H10W 90/00; H10B 80/00; H10D 80/30; H10W 72/865; H10W 72/884; H10W 90/20; H10W 90/24; H10W 90/724; H10W 90/732; H10W 90/734; H10W 90/752; H10W 90/754

(57) ABSTRACT

The technical idea of the inventive concept provides a semiconductor package including a package substrate including a base board layer, a plurality of conductive line patterns inside the base board layer, a plurality of conductive vias respectively connected to some of the plurality of conductive line patterns, and a plurality of lower pads disposed on a lower surface of the base board layer, respectively connected to some of the plurality of conductive vias and including at least one test lower pad to which a test signal for testing at least one of a first semiconductor chip and a semiconductor chip stack is applied, the first semiconductor chip disposed on the package substrate, and the semiconductor chip stack disposed on the package substrate. In a plan view of the semiconductor package, the at least one test lower pad is disposed between the first semiconductor chip and the semiconductor chip stack.

### CROSS-REFERENCE TO RELATED APPLICATION

This application is based on and claims priority under 35 U.S.C. § 119 to Korean Patent Application No. 10-2024-0147014, filed on Oct. 24, 2024, in the Korean Intellectual Property Office, the disclosure of which is incorporated by reference herein in its entirety.

### BACKGROUND

The inventive concept relates to a semiconductor package, and more particularly, to a semiconductor package including a semiconductor chip stack and a controller chip.

Non-volatile memories may maintain data stored therein even when power thereto is cut off. Recently, storage devices, such as an embedded multi-media card (eMMC), a universal flash storage (UFS), a solid state drive (SSD), and a memory card, including a flash-based non-volatile memory are widely used, and the storage devices are usefully used to store or move a lot of data.

A storage device may be implemented by a semiconductor package including a plurality of non-volatile semiconductor chips and a controller chip. The plurality of non-volatile semiconductor chips may be allocated to one or more channels and connected to the controller chip.

### SUMMARY

The inventive concept provides a semiconductor package with improved signal characteristics.

In addition, the problems to be solved by the technical idea of the inventive concept are not limited to the problem mentioned above, and other problems could be clearly understood by those of ordinary skill in the art from the description below.

According to an aspect of the inventive concept, there is provided a semiconductor package including a package substrate including a base board layer, a plurality of conductive line patterns inside the base board layer, a plurality of conductive vias respectively connected to some of the plurality of conductive line patterns by passing through a portion of the base board layer, and a plurality of lower pads disposed on a lower surface of the base board layer, respectively connected to some of the plurality of conductive vias and including at least one test lower pad connected to at least one of a first semiconductor chip and a semiconductor chip stack is applied, the first semiconductor chip disposed on the package substrate, and the semiconductor chip stack disposed on the package substrate and spaced apart from the first semiconductor chip in a horizontal direction. The at least one test lower pad is respectively connected to one or more of the plurality of conductive vias, and in a plan view of the semiconductor package, the at least one test lower pad is disposed between the first semiconductor chip and the semiconductor chip stack.

According to another aspect of the inventive concept, there is provided a semiconductor package including a package substrate including a base board layer, a plurality of conductive line patterns inside the base board layer, a plurality of conductive vias respectively connected to some of the plurality of conductive line patterns by passing through a portion of the base board layer, and a plurality of lower pads disposed on a lower surface of the base board layer and respectively connected to some of the plurality of conductive vias, a first semiconductor chip disposed on the package substrate, and a semiconductor chip stack disposed on the package substrate and spaced apart from the first semiconductor chip in a horizontal direction. The plurality of lower pads include at least one first lower pad and at least one second lower pad. The at least one second lower pad is connected to one or more of the plurality of conductive vias and electrically connected to a signal wiring through which the at least one second lower pad is connected to the first semiconductor chip and the semiconductor chip stack inside the package substrate. In a plan view of the semiconductor package, the at least one second lower pad is disposed between the first semiconductor chip and the semiconductor chip stack. Among the at least one first lower pad and the at least one second lower pad, an external connection terminal is disposed only on the at least one first lower pad.

According to another aspect of the inventive concept, there is provided a semiconductor package including a package substrate including a base board layer, a plurality of conductive line patterns inside the base board layer, a plurality of conductive vias respectively connected to some of the plurality of conductive line patterns by passing through a portion of the base board layer, a plurality of lower pads disposed on a lower surface of the base board layer and respectively connected to some of the plurality of conductive vias, and a plurality of upper pads disposed in an upper area of the base board layer and respectively connected to some of the plurality of conductive vias, a first semiconductor chip disposed on the package substrate, and a semiconductor chip stack disposed on the package substrate, spaced apart from the first semiconductor chip in a horizontal direction, and including a plurality of second semiconductor chips. The plurality of lower pads include a first lower pad and at least one second lower pad. The plurality of upper pads include a plurality of first upper pads including one connected to the first lower pad and a plurality of second upper pads connected to the at least one second lower pad. The at least one second lower pad is respectively connected to one or more of the plurality of conductive vias, the plurality of second upper pads are respectively connected to the one or more of the plurality of conductive vias. In a plan view of the semiconductor package, the at least one second lower pad is disposed between the first semiconductor chip and the semiconductor chip stack. Among the first lower pad and the at least one second lower pad, an external connection terminal is disposed only on the first lower pad.

### BRIEF DESCRIPTION OF THE DRAWINGS

Embodiments of the inventive concept will be more clearly understood from the following detailed description taken in conjunction with the accompanying drawings in which:

FIG. 1 is a block diagram illustrating a storage system including a semiconductor package according to an embodiment;

FIG. 2 is a block diagram illustrating a host device according to an embodiment;

FIG. 3 is a block diagram illustrating a storage device according to an embodiment;

FIG. 4 is a cross-sectional view illustrating a semiconductor package according to an embodiment;

FIG. 5 is a bottom view illustrating a semiconductor package according to an embodiment;

FIG. 6 is a bottom view illustrating a semiconductor package according to an embodiment;

FIG. 7 is a cross-sectional view illustrating a semiconductor package according to an embodiment; and

FIG. 8 is a cross-sectional view illustrating a semiconductor package according to an embodiment.

### DETAILED DESCRIPTION OF THE EMBODIMENTS

Hereinafter, embodiments are described in detail with reference to the accompanying drawings. Like reference numerals in the drawings denote like elements, and thus their repetitive description will be omitted. In the drawings below, the thicknesses or sizes of layers are exaggerated for convenience and clarity of description, and accordingly, may be somewhat different from real shapes and ratios.

The terms, e.g., “below”, “under”, “on”, “above”, and the like, indicating spatial positions are used to describe a relative position relationship between elements or patterns shown in the drawings only for the easiness of understanding and do not limit the technical idea of the inventive concept in any sense. The terms of relative spatial positions are intended to cover a change according to a direction of a semiconductor device in addition to the direction shown in the drawings. That is, a semiconductor device may be oriented in various directions when the semiconductor device is used (or manufactured), and even in such a case, the terms of positions used in the specification would be easily understood by those of ordinary skill in the art.

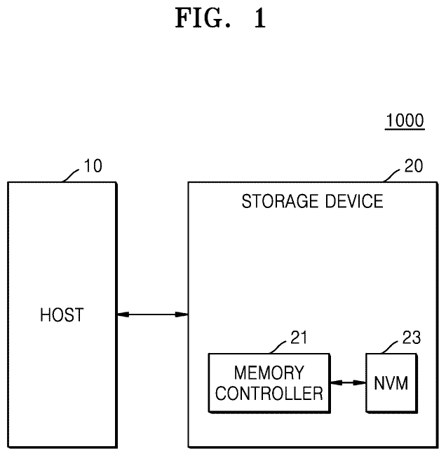

FIG. 1 is a block diagram illustrating a storage system 1000 including a semiconductor package according to an embodiment.

Referring to FIG. 1, the storage system 1000 of the inventive concept may include a host device 10 and a storage device 20.

The host device 10 may provide a logical address and a command to the storage device 20. During a write operation, the host device 10 may request the storage device 20 to program data to be written in a storage area of a non-volatile memory 23 corresponding to the logical address. During a read operation, the host device 10 may request, from the storage device 20, data to be read from the storage area of the non-volatile memory 23 corresponding to the logical address.

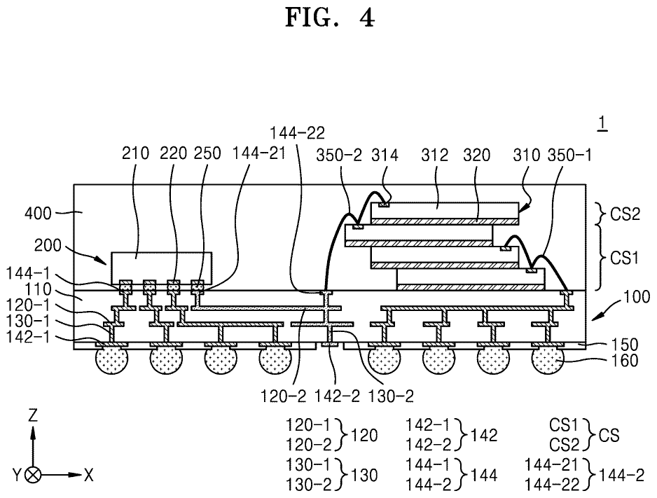

The storage device 20 may include a memory controller 21 and the non-volatile memory 23. The storage device 20 may correspond to a semiconductor package 1 (see FIG. 4) of the inventive concept. A detailed description of the semiconductor package 1 may be described below.

The memory controller 21 may generally control the storage device 20. Data read from the non-volatile memory 23 may be provided to the host device 10, and data provided from the host device 10 may be written in the non-volatile memory 23.

In response to a read/write request from the host device 10, the memory controller 21 may control the non-volatile memory 23 to read data stored in the non-volatile memory 23 or write data in the non-volatile memory 23.

Particularly, the memory controller 21 may control write, read, and erase operations on the non-volatile memory 23 by providing an address, a command, and a control signal to the non-volatile memory 23. In addition, data to be written and read data may be transmitted and received between the memory controller 21 and the non-volatile memory 23.

In an embodiment, the storage device 20 may be implemented by an internal memory embedded in an electronic device, and be, for example, an embedded universal flash storage (UFS) memory device or an embedded multi-media card (eMMC). In an embodiment, the storage device 20 may be implemented by an external memory detachably attached to an electronic device and be, for example, a UFS memory card, a compact flash (CF) memory card, a secure digital (SD) memory card, a micro secure digital (micro-SD) memory card, a mini secure digital (mini-SD) memory card, an extreme digital (xD) memory card, or a memory stick.

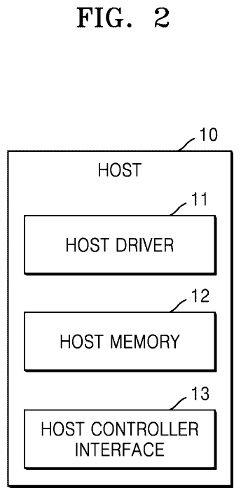

FIG. 2 is a block diagram illustrating the host device 10 according to an embodiment.

Referring to FIG. 2, the host device 10 may include a host driver 11, a host memory 12, and a host controller interface 13. In an embodiment, the host device 10 may be a UFS host according to a UFS standard.

In an embodiment, the host driver 11 may convert an input/output request generated by an application into a UFS command defined by the UFS standard and transmit the UFS command to the host controller interface 13. One input/output request may be converted into a plurality of UFS commands. The input/output request may be referred to as a task request. The UFS command may be a concept including UFS protocol information units (UPIUs) according to the UFS standard. The UFS command may be basically a command defined by a small computer systems interface (SCS1) standard but may be a UFS standard-exclusive command.

The host controller interface 13 may transmit a UFS command converted by a UFS driver to the storage device 20 (see FIG. 1). Although FIG. 2 shows that the host memory 12 is separated from the host controller interface 13, in some embodiments, the host memory 12 may be included in the host controller interface 13. The host controller interface 13 may control the host memory 12 to copy data in a normal area of the host memory 12 to a cache area of the host memory 12. The host controller interface 13 may transmit a logical address (e.g., a logical block address (LBA)) to the storage device 20 (see FIG. 1).

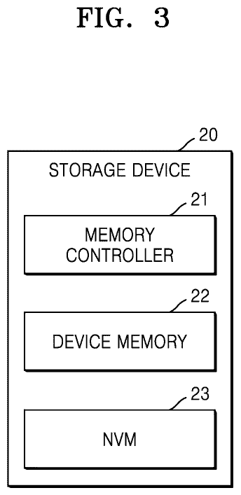

FIG. 3 is a block diagram illustrating the storage device 20 according to an embodiment. The storage device 20 is described with reference to FIG. 1 together.

Referring to FIG. 3, the storage device 20 may include the memory controller 21, a device memory 22, and the non-volatile memory 23. The description of the memory controller 21 and the non-volatile memory 23 was made above with reference to FIG. 1, and thus may be omitted herein.

The non-volatile memory 23 may include a memory cell array. For example, a plurality of memory cells included in the memory cell array may be non-volatile memory cells maintaining data stored therein even when power supplied thereto is cut off. Particularly, when the plurality of memory cells are non-volatile memory cells, the non-volatile memory 23 may be electrically erasable programmable read-only memory (EEPROM), flash memory, phase-change random access memory (PRAM), resistive random access memory (RRAM), nano-floating gate memory (NFGM), polymer random access memory (PoRAM), magnetoresistive random access memory (MRAM), ferroelectric random access memory (FeRAM), or the like. Hereinafter, the embodiments are described with respect to, as an example, a case where the plurality of memory cells are NAND flash memory cells, but the technical idea of the inventive concept is not limited thereto.

The memory cell array may include a plurality of memory blocks, and each memory block may have a planar structure or a three-dimensional structure. The memory cell array may include at least one of a single-level cell (SLC) block including SLCs, a multi-level cell (MLC) block including MLCs, a triple-level cell (TLC) block including TLCs, and a quad-level cell (QLC) block including QLCs.

The device memory 22 may temporarily store data to be written in the non-volatile memory 23 or data read from the non-volatile memory 23. The device memory 22 may include static random access memory (SRAM) or dynamic random access memory (DRAM).

FIG. 4 is a cross-sectional view illustrating the semiconductor package 1 according to an embodiment.

Referring to FIG. 4, the semiconductor package 1 may include a package substrate 100, a first semiconductor chip 200, and a semiconductor chip stack CS. The first semiconductor chip 200 and the semiconductor chip stack CS may be mounted on the package substrate 100. The first semiconductor chip 200 and the semiconductor chip stack CS may be disposed on the package substrate 100 and spaced apart from each other in a horizontal direction (the X direction and/or the Y direction).

In the specification, a direction parallel to a main surface of the package substrate 100 is defined as the horizontal direction (the X direction and/or the Y direction), and a direction perpendicular to the horizontal direction (the X direction and/or the Y direction) is defined as the vertical direction (the Z direction).

In addition, among two surfaces spaced from each other in the vertical direction (the Z direction), the surface spaced farther from an external connection terminal 160 may be referred to as the upper surface of a component, and the surface opposite to the upper surface may be referred to as the lower surface of the component.

The package substrate 100 may include a base board layer 110, a plurality of conductive line patterns 120, a plurality of conductive vias 130, and a protective layer 150. In an embodiment, the package substrate 100 may be a printed circuit board (PCB). For example, the package substrate 100 may be a multi-layer PCB. In another embodiment, the package substrate 100 may include a redistribution layer.

In an embodiment, the base board layer 110 may be made of at least one material selected from among phenol resin, epoxy resin, and polyimide. For example, the base board layer 110 may include at least one material selected from among flame retardant class 4 (FR4), tetrafunctional epoxy, polyphenylene ether, epoxy/polyphenylene oxide, bismaleimide triazine (BT), Thermount, cyanate ester, polyimide, and liquid crystal polymer.

The plurality of conductive line patterns 120 and the plurality of conductive vias 130 may be inside the base board layer 110. The plurality of conductive line patterns 120 and the plurality of conductive vias 130 may provide electrical connection paths between a plurality of lower pads 142 and a plurality of upper pads 144, inside the base board layer 110.

For example, the plurality of conductive line patterns 120 and the plurality of conductive vias 130 may include a conductive material including copper (Cu), gold (Au), silver (Ag), nickel (Ni), tungsten (W), aluminum (Al), or a combination thereof.

The package substrate 100 may include the plurality of lower pads 142 disposed on the lower surface of the base board layer 110 and the plurality of upper pads 144 disposed on the upper surface of the base board layer 110.

The plurality of lower pads 142 may include a bump pad 142-1 electrically and/or physically connected to the external connection terminal 160. The plurality of lower pads 142 may include one or more test lower pads 142-2 providing a test path for testing the first semiconductor chip 200 and/or the semiconductor chip stack CS. For convenience of description, the bump pad 142-1 may be referred to as a first lower pad 142-1, and each of the one or more test lower pads 142-2 may be referred to as a second lower pad 142-2.

In addition, the plurality of upper pads 144 may include a first upper pad 144-1 and a test upper pad 144-2. The test upper pad 144-2 may provide a test path for testing the first semiconductor chip 200 and/or the semiconductor chip stack CS. For convenience of description, the test upper pad 144-2 may be referred to as a second upper pad 144-2.

The plurality of conductive line patterns 120 and the plurality of conductive vias 130 may provide electrical connection paths between the one or more test lower pads 142-2 and a plurality of test upper pads 144-2, inside the base board layer 110. The one or more test lower pads 142-2, the plurality of test upper pads 144-2, and conductive line patterns 120 and conductive vias 130 electrically connected to the one or more test lower pads 142-2 and the plurality of test upper pads 144-2 may provide a test path for testing the first semiconductor chip 200 and/or the semiconductor chip stack CS.

For convenience of description, a conductive line pattern 120 and a conductive via 130 electrically connected to the first lower pad 142-1 and the first upper pad 144-1 may be referred to as a first conductive line pattern 120-1 and a first conductive via 130-1, respectively, and a conductive line pattern 120 and a conductive via 130 electrically connected to a test lower pad 142-2 and the test upper pad 144-2 may be referred to as a second conductive line pattern 120-2 and a second conductive via 130-2, respectively.

The second conductive line pattern 120-2 and the second conductive via 130-2 may provide a path through which a test signal between the first semiconductor chip 200 and the semiconductor chip stack CS is transmitted. In an embodiment, the second conductive line pattern 120-2, the second conductive via 130-2, and the test upper pad 144-2 may provide a path through which a test signal between the first semiconductor chip 200 and the semiconductor chip stack CS is transmitted. That is, a test signal applied to the test lower pad 142-2 may be applied to each of the first semiconductor chip 200 and the semiconductor chip stack CS.

In addition, at least some of a plurality of second conductive line patterns 120-2 and at least some of a plurality of second conductive vias 130-2 may provide a path through which a signal between the first semiconductor chip 200 and the semiconductor chip stack CS is transmitted. That is, the at least some of the plurality of second conductive line patterns 120-2 and the at least some of the plurality of second conductive vias 130-2 may function as a signal wiring. The test lower pad 142-2 may be electrically connected to the signal wiring. The test lower pad 142-2 may be electrically/physically connected to some of the plurality of second conductive vias 130-2.

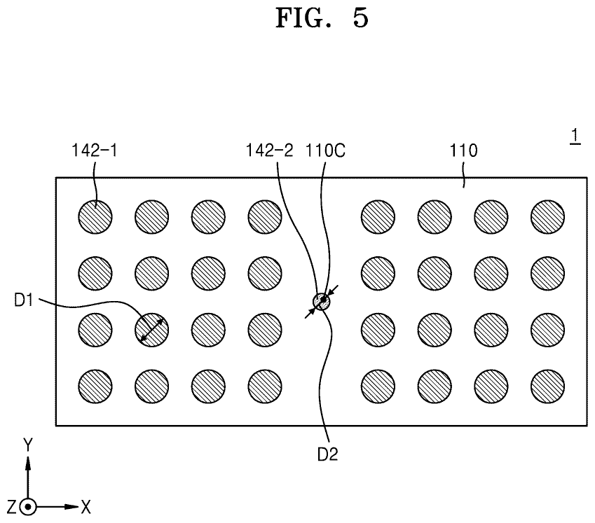

In a plan view, the signal wiring may be adjacent to the center of the package substrate 100. In a plan view, the signal wiring may be adjacent to a center 110C (see FIG. 5) of the base board layer 110.

In an embodiment, the first lower pad 142-1 and the second lower pad 142-2 may be located at the same vertical level, and the first upper pad 144-1 and the second upper pad 144-2 may be located at the same vertical level.

In a plan view, the second lower pad 142-2 may be between the first semiconductor chip 200 and the semiconductor chip stack CS. In a plan view, the second upper pad 144-2 may be between the first semiconductor chip 200 and the semiconductor chip stack CS. In an embodiment, in a plan view, at least some of the one or more second lower pads 142-2 and/or the plurality of second upper pads 144-2 may be between the first semiconductor chip 200 and the semiconductor chip stack CS. In another embodiment, in a plan view, the second lower pad 142-2 and/or the second upper pad 144-2 may be inside a footprint formed by the first semiconductor chip 200 and the semiconductor chip stack CS.

In an embodiment, an upper pad 144 adjacent to the semiconductor chip stack CS among the plurality of upper pads 144 electrically connected to the first semiconductor chip 200 may be the second upper pad 144-2. In a similar point of view, an upper pad 144 adjacent to the first semiconductor chip 200 among the plurality of upper pads 144 electrically connected to the semiconductor chip stack CS may be the second upper pad 144-2. In an embodiment, in a plan view, the second upper pad 144-2 may be surrounded by first upper pads 144-1.

In addition, at least some of the plurality of test upper pads 144-2 may be electrically connected to the first semiconductor chip 200, and at least some of the plurality of test upper pads 144-2 may be electrically connected to the semiconductor chip stack CS. That is, a test signal applied via the test lower pad 142-2 may be applied to each of the first semiconductor chip 200 and/or the semiconductor chip stack CS. A first test upper pad 144-21 electrically connected to the first semiconductor chip 200 via a connection member 250 and a second test upper pad 144-22 electrically connected to the semiconductor chip stack CS via a second wire 350-2 may be electrically connected to each other by the second conductive line pattern 120-2 and/or the second conductive via 130-2.

That is, the first test upper pad 144-21 may be electrically connected to the first semiconductor chip 200 via the connection member 250, and the second test upper pad 144-22 may be electrically connected to the semiconductor chip stack CS via the second wire 350-2. In a plan view, the second upper pad 144-2 may be surrounded by the first upper pads 144-1. In an embodiment, for convenience of description, the connection member 250 may be referred to as a first connection member, and the second wire 350-2 may be referred to as a second connection member.

The one or more test lower pads 142-2 and the plurality of test upper pads 144-2 may be used to determine whether the first semiconductor chip 200 and/or the semiconductor chip stack CS are/is defective. The one or more test lower pads 142-2 may be exposed without being completely covered by the protective layer 150.

The protective layer 150 may be a layer protecting the base board layer 110 from external physical/chemical damage. The protective layer 150 may be disposed on the upper surface and/or the lower surface of the base board layer 110. For example, the protective layer 150 may include a solder resist (SR). Although FIG. 4 illustrates that the protective layer 150 is disposed only on the lower surface of the base board layer 110, the technical idea of the inventive concept is not limited thereto. In another embodiment, the protective layer 150 may be disposed on the upper surface of the base board layer 110. In another embodiment, the protective layer 150 may not be disposed on the lower surface of the base board layer 110.

The protective layer 150 may expose the one or more test lower pads 142-2 therethrough. In an embodiment, at least a portion of the one or more test lower pads 142-2 may not overlap the protective layer 150 in the vertical direction (the Z direction). In another embodiment, the one or more test lower pads 142-2 may not overlap the protective layer 150 in the vertical direction (the Z direction).

The semiconductor package 1 may further include the external connection terminal 160 electrically and/or physically connected to the first lower pad 142-1 of the package substrate 100. The external connection terminal 160 may be on the lower surface of the first lower pad 142-1. The external connection terminal 160 may include a conductive material including, for example, tin (Sn), lead (Pb), Ag, Cu, or a combination thereof. The external connection terminal 160 may be formed using, for example, a solder ball. The external connection terminal 160 may connect the semiconductor package 1 to a circuit board, another semiconductor package, an interposer, or a combination thereof. According to one example, the external connection terminal 160 may not be disposed in an opening of the protective layer 150 which exposes the one or more test lower pads 142-2.

The first semiconductor chip 200 may be disposed on the package substrate 100. The first semiconductor chip 200 may include a first substrate 210 and a first chip pad 220. The first semiconductor chip 200 may correspond to the memory controller 21 described with reference to FIGS. 1 and 3. That is, the first semiconductor chip 200 may control an operation of the semiconductor chip stack CS.

The first substrate 210 may include, for example, silicon (Si). Alternatively, the first substrate 210 may include a semiconductor element, such as germanium (Ge), or a compound semiconductor, such as silicon carbide (SiC), gallium arsenide (GaAs), indium arsenide (InAs), or indium phosphide (InP). The first substrate 210 may include various types of individual devices. For example, the first substrate 210 may include a metal-oxide-semiconductor field effect transistor (MOSFET), such as a complementary metal-oxide-semiconductor (CMOS) transistor, a system large scale integration (LSI) chip, an active device, a passive device, and the like.

The first substrate 210 may have a first active surface and a first inactive surface opposite to the first active surface. For example, the first active surface may be adjacent to the lower surface of the first semiconductor chip 200, and the first inactive surface may be the upper surface of the first semiconductor chip 200.

The first chip pad 220 may be disposed in a lower area of the first substrate 210. The first semiconductor chip 200 may be electrically connected to the package substrate 100 via the first chip pad 220. The connection member 250 may be between the package substrate 100 and the first semiconductor chip 200. The connection member 250 may be between the upper pad 144 of the package substrate 100 and the first chip pad 220 of the first semiconductor chip 200. The connection member 250 may be between the test upper pad 144-2 of the package substrate 100 and the first chip pad 220 of the first semiconductor chip 200. For example, the connection member 250 may include a conductive pillar and/or a solder bump.

A first semiconductor chip stack CS1 may be disposed on the package substrate 100. The first semiconductor chip stack CS1 may be disposed on the package substrate 100 and spaced apart from the first semiconductor chip 200 in the horizontal direction (the X direction and/or the Y direction). The first semiconductor chip stack CS1 may include one or more second semiconductor chips 310. A second semiconductor chip stack CS2 may be disposed on the first semiconductor chip stack CS1. The second semiconductor chip stack CS2 may include one or more second semiconductor chips 310. Although FIG. 4 illustrates that the first semiconductor chip stack CS1 includes three second semiconductor chips 310 and the second semiconductor chip stack CS2 includes one second semiconductor chip 310, the technical idea of the inventive concept is not limited thereto. The second semiconductor chip 310 may correspond to the non-volatile memory 23 described with reference to FIGS. 1 and 3.

A plurality of second semiconductor chips 310 may be stacked in the vertical direction (the Z direction). For example, among two second semiconductor chips 310 adjacent to each other, the upper second semiconductor chip 310 may be disposed on the lower second semiconductor chip 310 and offset in a particular direction more than the lower second semiconductor chip 310.

When a semiconductor chip stack includes the plurality of second semiconductor chips 310, the plurality of second semiconductor chips 310 may be stacked stepwise in the semiconductor chip stack. That is, a second semiconductor chip 310 may be disposed on a second semiconductor chip 310 located at a lower position by being offset in a particular direction more than the second semiconductor chip 310 located at the lower position. For example, as shown in FIG. 4, a second semiconductor chip 310 located at a higher position may be disposed on a second semiconductor chip 310 located at a lower position by being offset in a negative first horizontal direction (the −X direction) from the second semiconductor chip 310 located at the lower position.

For example, the second semiconductor chip 310 may be a memory semiconductor chip. In an embodiment, the second semiconductor chip 310 may include a memory semiconductor device, and the memory semiconductor device may be a non-volatile memory semiconductor device, such as flash memory, PRAM, MRAM, FeRAM, or RRAM. The flash memory may be, for example, vertical NAND (V-NAND) flash memory.

Each of the plurality of second semiconductor chips 310 may include a second substrate 312 and a second chip pad 314. The second substrate 312 may include, for example, Si. Alternatively, the second substrate 312 may include a semiconductor element, such as Ge, or a compound semiconductor, such as SiC, GaAs, InAs, or InP. Alternatively, the second substrate 312 may have a silicon on insulator (SOI) structure. For example, the second substrate 312 may include a buried oxide (BOX) layer. The second substrate 312 may include a conductive area, for example, an impurity-doped well. The second substrate 312 may have various device isolation structures, such as a shallow trench isolation (STI) structure.

The second substrate 312 may have a second active surface and a second inactive surface opposite to the second active surface. For example, the second active surface may be adjacent to the upper surface of the second semiconductor chip 310, and the second inactive surface may be the lower surface of the second semiconductor chip 310.

The second chip pad 314 may be disposed in an upper area of the second semiconductor chip 310. The second chip pad 314 may be provided to a portion of the upper surface of each second semiconductor chip 310, which is exposed according to offset of the plurality of second semiconductor chips 310. The second chip pad 314 may be exposed from a passivation layer provided to the upper surface of the second semiconductor chip 310. Some of a plurality of second chip pads 314 may be data pads for transmission of a data signal. Some of the plurality of second chip pads 314 may be connected to the first upper pad 144-1 via a first wire 350-1, and some of the plurality of second chip pads 314 may be connected to the second upper pad 144-2 via the second wire 350-2. That is, the second wire 350-2 may provide a path for testing the plurality of second semiconductor chips 310.

Each of the plurality of second semiconductor chips 310 may be stacked on the package substrate 100 and/or an immediately lower second semiconductor chip 310 through an adhesive layer 320. The adhesive layer 320 may be provided on the lower surface of each of the plurality of second semiconductor chips 310. The adhesive layer 320 may be provided between every two adjacent second semiconductor chips 310 among the plurality of second semiconductor chips 310 and/or the lowermost second semiconductor chip 310 and the package substrate 100. For example, the adhesive layer 320 may include an inorganic adhesive or a polymer adhesive. For example, the polymer adhesive may include a thermosetting polymer or a thermoplastic polymer.

In addition, although FIG. 4 shows that the first wire 350-1 is electrically and/or physically connected to two lower second semiconductor chips 310 of the semiconductor chip stack CS and the second wire 350-2 is electrically and/or physically connected to two upper second semiconductor chips 310 of the semiconductor chip stack CS, the technical idea of the inventive concept is not limited thereto. The first wire 350-1 and/or the second wire 350-2 may be electrically and/or physically connected to second semiconductor chips 310 disposed at various positions.

The semiconductor package 1 may further include a sealing material 400 covering the first semiconductor chip 200 and the semiconductor chip stack CS on the package substrate 100. The sealing material 400 may seal the first semiconductor chip 200 and the plurality of second semiconductor chips 310 of the semiconductor chip stack CS to protect the same from external physical/chemical damage. The side surface of the sealing material 400 may be aligned with the side surface of the package substrate 100 in the vertical direction (the Z direction).

The sealing material 400 may include an insulating material, e.g., a thermosetting polymer, such as an epoxy resin, or a thermoplastic polymer, such as polyimide. In addition, the scaling material 400 may include a resin, for example, an Ajinomoto build-up film (ABF), FR-4, a BT resin, or the like, including a reinforcing material, such as an inorganic filler, in addition to a thermosetting polymer or a thermoplastic polymer. In addition, the sealing material 400 may include a molding material, such as an epoxy molding compound (EMC), or a photosensitive material, such as a photoimageable encapsulant (PIE). In the semiconductor package 1 of the present embodiment, the sealing material 400 may include, for example, an EMC. However, the material of the sealing material 400 is not limited to the materials described above.

A general semiconductor package has a relatively high stub when a test path for testing a first semiconductor chip and/or a semiconductor chip stack is formed. Therefore, a glitch due to reflection may occur, and thus, the signal characteristics of a package substrate may be bad.

However, the semiconductor package 1 of the inventive concept may have the second lower pad 142-2 formed by forming the second conductive via 130-2 on a signal transfer path between the first semiconductor chip 200 and the semiconductor chip stack CS. Therefore, the length of a test path may be shortened, and the stub of a test signal may be reduced, thereby improving the signal characteristics in the package substrate 100. That is, the semiconductor package 1 of the inventive concept may provide a test signal with a reduced stub, thereby reducing a glitch through reflection. Therefore, the electrical reliability of the semiconductor package 1 may increase.

FIG. 5 is a bottom view illustrating the semiconductor package 1 according to an embodiment.

The semiconductor package 1 is described with reference to FIG. 4 together.

Referring to FIG. 5, the first lower pad 142-1 with which the external connection terminal 160 is in contact and the second lower pad 142-2 for a test are shown. As described above, a test on the first semiconductor chip 200 and/or the semiconductor chip stack CS may be performed by applying a test signal to the second lower pad 142-2. The second lower pad 142-2 may be disposed adjacent to the center 110C of the base board layer 110. In an embodiment, in a plan view, the center 110C of the base board layer 110 may coincide with the center of the package substrate 100. In another embodiment, in a plan view, the center 110C of the base board layer 110 may be separated from the center of the package substrate 100.

In addition, in a plan view, the second lower pad 142-2 may be surrounded by first lower pads 142-1. That is, in a plan view, the second lower pad 142-2 may be surrounded by external connection terminals 160.

A diameter D1 of the first lower pad 142-1 may be greater than a diameter D2 of the second lower pad 142-2. That is, the horizontal cross-sectional area of the first lower pad 142-1 may be greater than the horizontal cross-sectional area of the second lower pad 142-2.

In a plan view, in the semiconductor package 1 of the inventive concept, the second lower pad 142-2 for testing the first semiconductor chip 200 and/or the semiconductor chip stack CS is disposed adjacent to the center 110C of the base board layer 110. In a plan view, when the second lower pad 142-2 is disposed adjacent to the center 110C of the base board layer 110, the length of a test path may be shortened, thereby improving the signal characteristics in the package substrate 100. That is, the semiconductor package 1 of the inventive concept may provide a test signal with a reduced stub, thereby reducing a glitch through reflection. Therefore, the electrical reliability of the semiconductor package 1 may increase.

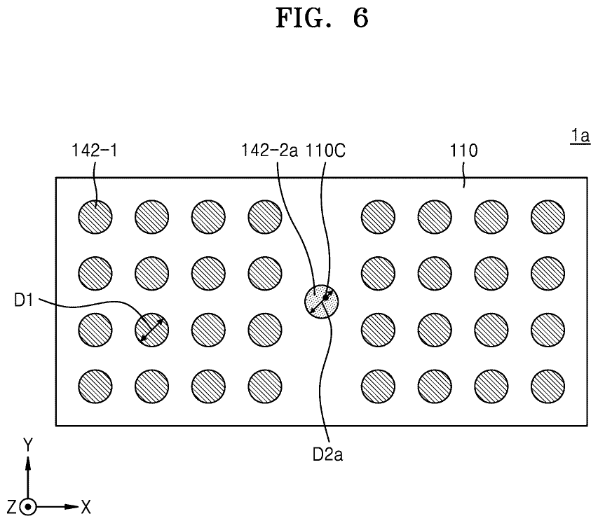

FIG. 6 is a bottom view illustrating a semiconductor package 1a according to an embodiment. The semiconductor package 1a is described with reference to FIGS. 4 and 5 together.

The semiconductor package 1a shown in FIG. 6 is almost the same as or similar to the semiconductor package 1 shown in FIG. 5 except that a second lower pad 142-2a of FIG. 6 is different from the second lower pad 142-2 of FIG. 5. Therefore, the description made with respect to components with reference to FIG. 5 is omitted or simply repeated.

Referring to FIG. 6, a diameter D2a of the second lower pad 142-2a may be substantially the same as the diameter D1 of the first lower pad 142-1. That is, the horizontal cross-sectional area of the second lower pad 142-2a may be the same as the horizontal cross-sectional area of the first lower pad 142-1. When the horizontal cross-sectional area of the second lower pad 142-2a increases, the first semiconductor chip 200 and/or the semiconductor chip stack CS may be easily tested.

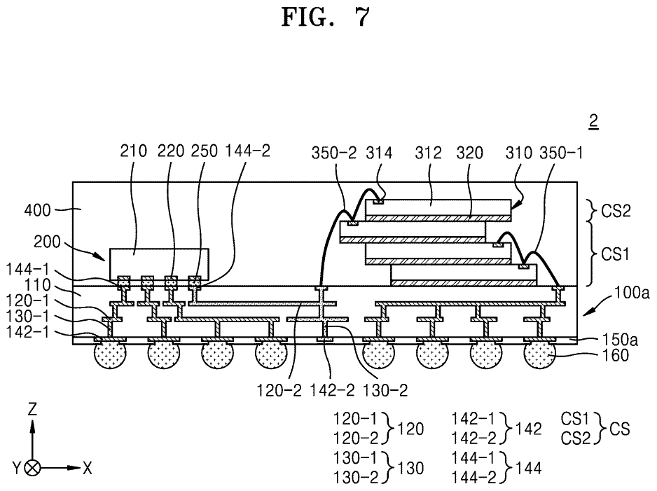

FIG. 7 is a cross-sectional view illustrating a semiconductor package 2 according to an embodiment. The semiconductor package 2 is described with reference to FIG. 4 together.

The semiconductor package 2 shown in FIG. 7 is almost the same as or similar to the semiconductor package 1 shown in FIG. 4 except that a protective layer 150a of FIG. 7 is different from the protective layer 150 of FIG. 4. Therefore, the description made with respect to components with reference to FIG. 4 is omitted or simply repeated.

Referring to FIG. 7, the protective layer 150a may cover the lower surface of the second lower pad 142-2. In an embodiment, the protective layer 150a may entirely cover the lower surface of the second lower pad 142-2. That is, the second lower pad 142-2 may not be exposed to the outside of the semiconductor package 2.

As described above, the second lower pad 142-2 may be used to test the first semiconductor chip 200 and the semiconductor chip stack CS. Therefore, when the first semiconductor chip 200 and the semiconductor chip stack CS are tested, at least a portion of the protective layer 150a may be removed. In more detail, when the first semiconductor chip 200 and the semiconductor chip stack CS are tested, at least a portion of the protective layer 150a may be removed such that at least a portion of the lower surface of the second lower pad 142-2 is exposed to the outside.

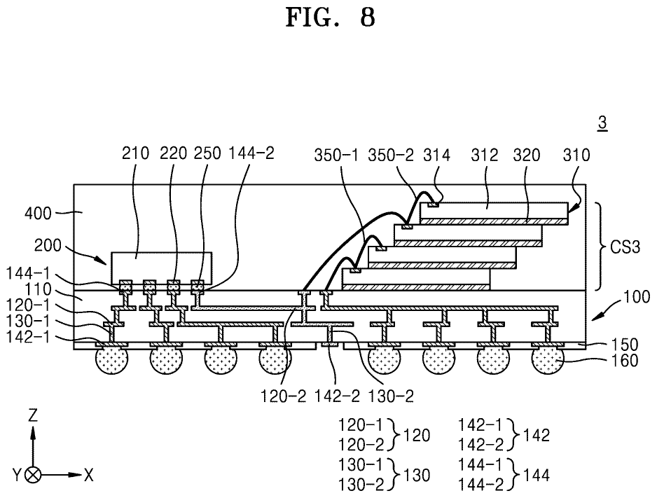

FIG. 8 is a cross-sectional view illustrating a semiconductor package 3 according to an embodiment. The semiconductor package 3 is described with reference to FIG. 4 together.

The semiconductor package 3 shown in FIG. 8 is almost the same as or similar to the semiconductor package 1 shown in FIG. 4 except that the former includes a third semiconductor chip stack CS3 disposed on the package substrate 100 and spaced apart from the first semiconductor chip 200 in the horizontal direction (the X direction and/or the Y direction). Therefore, the description made with respect to components with reference to FIG. 4 is omitted or simply repeated.

Referring to FIG. 8, the semiconductor package 3 may include the third semiconductor chip stack CS3 spaced apart from the first semiconductor chip 200 in the horizontal direction (the X direction and/or the Y direction) and including four second semiconductor chips 310. Although FIG. 8 illustrates that the third semiconductor chip stack CS3 includes four second semiconductor chips 310, the technical idea of the inventive concept is not limited thereto. For example, the third semiconductor chip stack CS3 may include three or less second semiconductor chips 310 or five or more second semiconductor chips 310.

In addition, although FIG. 8 shows that the first wire 350-1 is electrically and/or physically connected to two lower second semiconductor chips 310 of the third semiconductor chip stack CS3 and the second wire 350-2 is electrically and/or physically connected to two upper second semiconductor chips 310 of the third semiconductor chip stack CS3, the technical idea of the inventive concept is not limited thereto. The first wire 350-1 and/or the second wire 350-2 may be electrically and/or physically connected to second semiconductor chips 310 disposed at various positions.

Although not shown in FIGS. 4, 7, and 8, the first semiconductor chip 200 and the semiconductor chip stack CS may be variously disposed on the package substrate 100. For example, the semiconductor chip stack CS may be stacked on the first semiconductor chip 200, or a plurality of semiconductor chip stacks CS may be disposed on the package substrate 100 and spaced apart from each other in the horizontal direction (the X direction and/or the Y direction).

While the inventive concept has been particularly shown and described with reference to embodiments thereof, it will be understood that various changes in form and details may be made therein without departing from the spirit and scope of the following claims.

What is claimed is:

1. A semiconductor package comprising:
a package substrate comprising a base board layer, a plurality of conductive line patterns inside the base board layer, a plurality of conductive vias respectively connected to some of the plurality of conductive line patterns by passing through a portion of the base board layer, and a plurality of lower pads disposed on a lower surface of the base board layer, respectively connected to some of the plurality of conductive vias and comprising at least one test lower pad connected to at least one of a first semiconductor chip and a semiconductor chip stack;
the first semiconductor chip disposed on the package substrate; and
the semiconductor chip stack disposed on the package substrate and spaced apart from the first semiconductor chip in a horizontal direction,
wherein the at least one test lower pad is respectively connected to one or more of the plurality of conductive vias, and
in a plan view of the semiconductor package, the at least one test lower pad is disposed between the first semiconductor chip and the semiconductor chip stack.

2. The semiconductor package of claim 1, wherein at least a portion of a lower surface of the at least one test lower pad is exposed to an outside of the semiconductor package.

3. The semiconductor package of claim 1, wherein an entire lower surface of the at least one test lower pad is not exposed to an outside of the semiconductor package.

4. The semiconductor package of claim 1, wherein the plurality of lower pads further comprise a first lower pad on which an external connection terminal is disposed, the at least one test lower pad includes a second lower pad, and a diameter of the second lower pad is the same as a diameter of the first lower pad.

5. The semiconductor package of claim 1, wherein the plurality of lower pads further comprise a first lower pad on which an external connection terminal is disposed, the at least one test lower pad includes a second lower pad, and a diameter of the second lower pad is less than a diameter of the first lower pad.

6. The semiconductor package of claim 1, wherein the at least one test lower pad is connected to each of the first semiconductor chip and the semiconductor chip stack.

7. The semiconductor package of claim 1, wherein the first semiconductor chip is configured to control an operation of the semiconductor chip stack.

8. A semiconductor package comprising:
a package substrate comprising a base board layer, a plurality of conductive line patterns inside the base board layer, a plurality of conductive vias respectively connected to some of the plurality of conductive line patterns by passing through a portion of the base board layer, and a plurality of lower pads disposed on a lower surface of the base board layer and respectively connected to some of the plurality of conductive vias;
a first semiconductor chip disposed on the package substrate; and
a semiconductor chip stack disposed on the package substrate and spaced apart from the first semiconductor chip in a horizontal direction,
wherein the plurality of lower pads comprise at least one first lower pad and at least one second lower pad,
the at least one second lower pad is connected to one or more of the plurality of conductive vias and electrically connected to a signal wiring through which the at least one second lower pad is connected to the first semiconductor chip and the semiconductor chip stack inside the package substrate,
in a plan view of the semiconductor package, the at least one second lower pad is disposed between the first semiconductor chip and the semiconductor chip stack, and
among the at least one first lower pad and the at least one second lower pad, an external connection terminal is disposed only on the at least one first lower pad.

9. The semiconductor package of claim 8, further comprising a protective layer disposed on the lower surface of the base board layer and exposing at least a portion of a lower surface of the at least one second lower pad.

10. The semiconductor package of claim 8, further comprising a protective layer disposed on the lower surface of the base board layer and entirely covering a lower surface of the at least one second lower pad.

11. The semiconductor package of claim 8, wherein, in the plan view, the signal wiring is disposed adjacent to a center of the package substrate.

12. The semiconductor package of claim 8, wherein a horizontal cross-sectional area of the at least one second lower pad is the same as a horizontal cross-sectional area of the at least one first lower pad.

13. The semiconductor package of claim 8, wherein a horizontal cross-sectional area of the at least one second lower pad is different from a horizontal cross-sectional area of the at least one first lower pad.

14. The semiconductor package of claim 8, wherein, in the plan view, the at least one second lower pad is surrounded by the at least one first lower pad.

15. The semiconductor package of claim 8, wherein the signal wiring comprises at least some of the plurality of conductive line patterns and at least some of the plurality of conductive vias.

16. The semiconductor package of claim 8, wherein the semiconductor chip stack comprises a plurality of second semiconductor chips stacked by being offset.

17. A semiconductor package comprising:
a package substrate comprising a base board layer, a plurality of conductive line patterns inside the base board layer, a plurality of conductive vias respectively connected to some of the plurality of conductive line patterns by passing through a portion of the base board layer, a plurality of lower pads disposed on a lower surface of the base board layer and respectively connected to some of the plurality of conductive vias, and a plurality of upper pads disposed in an upper area of the base board layer and respectively connected to some of the plurality of conductive vias;
a first semiconductor chip disposed on the package substrate; and
a semiconductor chip stack disposed on the package substrate, spaced apart from the first semiconductor chip in a horizontal direction, and comprising a plurality of second semiconductor chips,
wherein the plurality of lower pads comprise a first lower pad and at least one second lower pad,
the plurality of upper pads comprise a plurality of first upper pads including one connected to the first lower pad and a plurality of second upper pads connected to the at least one second lower pad,
the at least one second lower pad is respectively connected to one or more of the plurality of conductive vias, the plurality of second upper pads are respectively connected to the one or more of the plurality of conductive vias,
in a plan view of the semiconductor package, the at least one second lower pad is disposed between the first semiconductor chip and the semiconductor chip stack, and
among the first lower pad and the at least one second lower pad, an external connection terminal is disposed only on the first lower pad.

18. The semiconductor package of claim 17, wherein, in the plan view, the plurality of second upper pads are surrounded by the plurality of first upper pads.

19. The semiconductor package of claim 17, wherein the at least one second lower pad is electrically connected to a signal wiring connected between the first semiconductor chip and the semiconductor chip stack inside the package substrate.

20. The semiconductor package of claim 17, wherein the plurality of second semiconductor chips comprise a memory chip.
